(19) United States
(12) Patent Application Publication
(10) Pub. No.: US 2010/0246854 A1
(43) Pub. Date: Sep. 30, 2010

(54) SOUND REPRODUCTION

(75) Inventor: Ronaldus Maria Aarts, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/161,817

(22) PCT Filed: Jan. 12, 2007
(86) PCT No.: PCT/IB07/50097

§ 371 Date: Jul. 23, 2008

(30) Foreign Application Priority Data
Jan. 27, 2006 (EP) 06100926.2

(51) Int. Cl. H03G 5/16

(52) U.S. Cl. 381/101

(57) ABSTRACT

A sound system (8) comprises a transducer unit (1) and a frequency mapping device (2). The transducer unit comprises an array of transducers (14). The frequency mapping device is arranged for mapping a frequency range of an audio input signal (Vᵢₙ) onto a frequency at which the transducer unit has a maximum efficiency, such as a resonance frequency or the Helmholtz frequency of the transducer unit. The transducer unit (1) may comprise a dedicated transducer (13) is coupled to the frequency mapping device (2) for producing the Helmholtz frequency of the transducer unit (1). The sound system may additionally comprise a sound processing device (3) arranged for steering sound produced by the array of transducers (14).

The present invention relates to sound reproduction. More in particular, the present invention relates to a sound system capable of efficiently reproducing a specific audio frequency range, such as the bass range, in addition to other audio frequency ranges.

It is well known that audio transducers, such as loudspeakers, have a limited frequency range in which they can faithfully render sound at a certain minimum sound level. High fidelity audio systems typically have relatively small transducers (tweeters) for reproducing the high frequency range, and relatively large transducers (woofers) for reproducing the low frequency range. The transducers units (that is, enclosures in which transducers are accommodated) required to reproduce the lowest audible frequencies (approximately 20-100 Hz) at a suitable sound level take up a substantial amount of space. For this reason, so-called subwoofers are typically accommodated in separate transducer units. Consumers, however, often prefer compact audio sets which necessarily have small transducer units. In addition, consumers often are not keen to accommodate numerous transducer units, including subwoofer units, in their homes.

It has been suggested to solve the transducer size problem by using psycho-acoustic phenomena such as “virtual pitch”. By creating harmonics of low-frequency signal components it is possible to suggest the presence of such signal components without actually reproducing these components. However, this solution is no substitute for actually producing low-frequency (“bass”) signal components.

International Patent Application WO 2005/027569 (Philips) discloses a device for producing a driving signal for a transducer, such as a loudspeaker. The driving signal has a frequency substantially equal to a resonance frequency of the transducer. By driving the transducer at a resonance frequency, a very efficient sound reproduction at low frequencies can be achieved. It has been found, however, that to achieve high sound levels at certain resonance frequencies, the displacement of the transducer becomes very large, in some cases even prohibitively large.

It is an object of the present invention to overcome these and other problems of the Prior Art and to provide a sound system which allows an efficient reproduction of a specific frequency band, such as the bass band, using relatively small transducers units without requiring additional transducer units.

Accordingly, the present invention provides a sound system, comprising a transducer unit and a frequency mapping device, wherein the transducer unit comprises an array of transducers, and wherein the frequency mapping device is arranged for mapping a frequency range of an audio input signal onto a frequency at which the transducer unit has a maximum efficiency.

By providing an array of transducers, that is, at least two transducers in a single transducer unit, it is possible to faithfully reproduce various frequency ranges. By providing a frequency mapping device arranged for mapping a frequency range of an audio input signal onto a frequency at which the transducer unit has the maximum efficiency and/or the highest sensitivity, a very efficient reproduction of a selected frequency range can be attained. As a result, it is for example possible to reproduce bass frequencies very efficiently, using a relatively small transducer unit. An additional subwoofer unit, which takes up extra spaces, requires separate wiring and adds to the cost, is in the sound system of the present invention not required.

The frequency at which the transducer unit has a maximum efficiency may be a resonance frequency of the transducer or transducer unit, preferably the resonance frequency producing the highest sound pressure level. However, it is preferred that the frequency at which the transducer unit has a maximum efficiency is the Helmholtz frequency of the transducer unit. That is, the frequency mapping device is preferably arranged for mapping a frequency range of an audio input signal onto the Helmholtz frequency of the transducer unit.

It is noted that in the present document, a transducer unit is understood to comprise an enclosure in which one or more transducers are accommodated, a transducer being a device, such as a loudspeaker, for reproducing sound. It is further noted that the mapping of a frequency range onto the Helmholtz frequency of a transducer unit is discussed in more detail in European Patent Application EP 05108634.6 (File Reference PH 000806 EP1) and any Patents and Patent Applications derived from said European Patent Application, the entire contents of which are herewith incorporated in this document.

The array of transducers, which may comprise two, three or more transducers, may advantageously be used for providing directional sound. Accordingly, in a preferred embodiment of the present invention, the sound system further comprises a sound processing device arranged for steering sound produced by the array of transducers. This allows to direct the sound to the user of the system, making the positioning of the transducer unit(s) of the system less critical.

In a first embodiment, a dedicated transducer is coupled to the frequency mapping device so as to produce a resonance frequency or the Helmholtz frequency of the transducer unit. In this embodiment, a separate transducer may be provided, in addition to the array of transducers, for reproducing the Helmholtz frequency. This dedicated transducer may be specifically designed for this purpose.

In a second embodiment, the array of transducers is coupled to the frequency mapping device so as to produce a resonance frequency or the Helmholtz frequency of the transducer unit. In this embodiment, the dedicated transducer may be omitted as the resonance or Helmholtz frequency is reproduced by the array of transducers. The second embodiment advantageously further comprises combination units for combining a frequency mapped signal with array signals.

The array of the transducer unit may comprise at least three transducers, preferably at least five transducers. Larger numbers of transducers are also possible, for example ten or twenty transducers in a single transducer unit.

Although the transducer unit may comprise only transducers and an enclosure, in an advantageous embodiment the frequency mapping device and the sound processing device are incorporated in the transducer unit. Accordingly, the transducer unit may receive a regular audio input signal and reproduce this signal without requiring additional components.

The present invention further provides a transducer unit for use in the sound system defined above. Such a transducer unit, which comprises an array of transducers and which may additionally comprise a dedicated transducer, is arranged for reproducing its Helmholtz frequency. A frequency mapping device and/or a signal processing device may be incorporated in the transducer unit.

The present invention also provides a method of reproducing sound using a transducer unit comprising an array of transducers, the method comprising the step of mapping a frequency range of an audio input signal onto the Helmholtz frequency of the transducer unit. The method of the present invention may further comprise the step of steering sound produced by the array of transducers.

The present invention additionally provides a computer program product for carrying out the method as defined above. A computer program product may comprise a set of computer executable instructions stored on a data carrier, such as a CD or a DVD. The set of computer executable instructions, which allow a programmable computer to carry out the method as defined above, may also be available for downloading from a remote server, for example via the Internet.

The present invention will further be explained below with reference to exemplary embodiments illustrated in the accompanying drawings, in which:

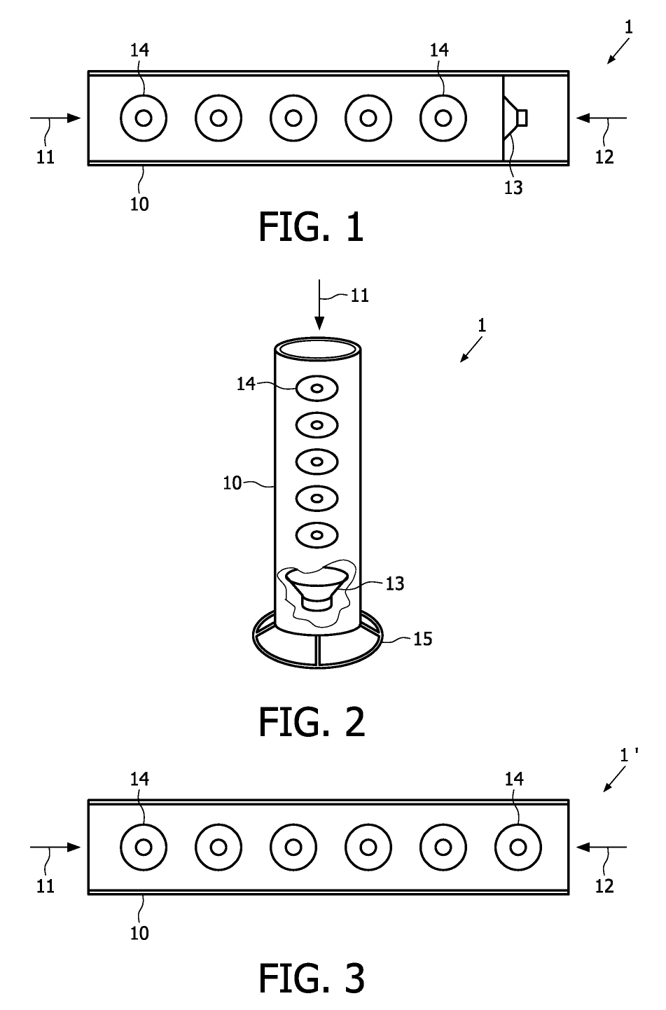

FIG. 1 schematically shows, in cross-sectional view, a first embodiment of a transducer unit according to the present invention.

FIG. 2 schematically shows, in perspective, a second embodiment of a transducer unit according to the present invention.

FIG. 3 schematically shows, in cross-sectional view, a third embodiment of a transducer unit according to the present invention.

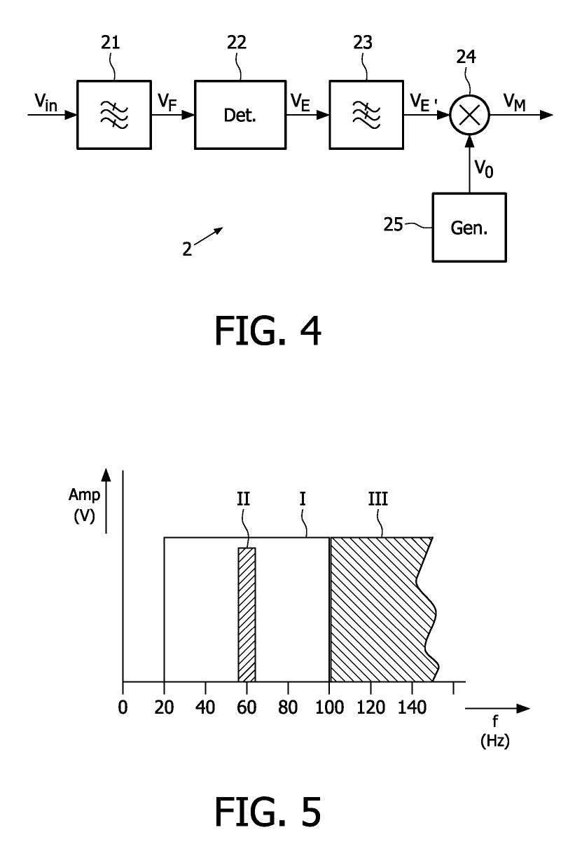

FIG. 4 schematically shows a frequency mapping device as used in the present invention.

FIG. 5 schematically shows the mapping of frequency ranges as used in the present invention.

FIG. 6 schematically shows a first embodiment of a sound system according to the present invention.

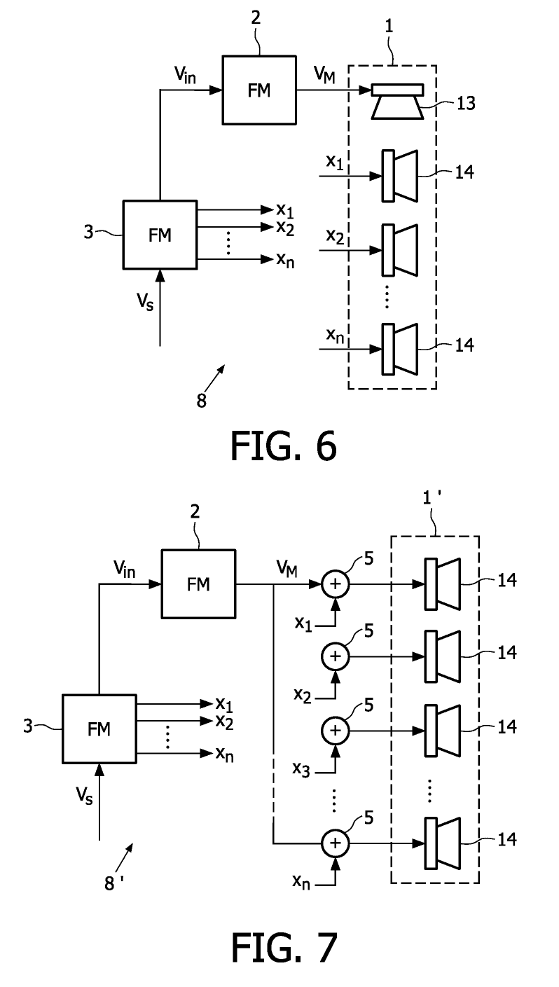

FIG. 7 schematically shows a second embodiment of a sound system according to the present invention.

The transducer unit 1 shown merely by way of non-limiting example in FIG. 1 comprises an elongate hollow body 10 having a first open end 11 and a second open end 12. In the example shown, the hollow body 10 is essentially tubular, having a circular cross-section. However, other cross-sectional shapes are also possible, such as rectangular, square, triangular, hexagonal, octagonal, etc. Transducers 13 and 14 are arranged in the hollow body 10. The single first transducer 13 serves to reproduce bass frequencies. Several second transducers 14, which may serve to reproduce all audio frequencies except bass frequencies, constitute a transducer array which can be used to direct sound. It will be understood that two or more first transducers 13 may be provided. Similarly, the number of second transducers 14 is not necessarily equal to five but may range from two to ten transducers or more, although a single second transducer 14 may suffice if sound steering is not required.

In accordance with an important aspect of the present invention, the first transducer 13 is arranged to operate at a frequency at which the transducer unit is most efficient and/or most sensitivity, such as a resonance frequency or the Helmholtz frequency of the transducer unit 1. This results in a high sound level at a low input power. The transducer unit 1 is designed to have a resonance or Helmholtz frequency in the bass range, preferably at about 55 Hz, although for example 45 Hz, 50 Hz, 60 Hz or 70 Hz is also feasible.

It is noted that the well-known Helmholtz frequency is the frequency at which the so-called anti-resonance occurs in the transducer unit, resulting in a minimum excursion of the transducer.

In accordance with an important further aspect of the present invention, a frequency range is essentially mapped upon the most efficient frequency of the transducer unit, such as the resonance or Helmholtz frequency. This allows the mapped frequency range, preferably a bass frequency range, to be reproduced with a very high efficiency. This frequency mapping will later be explained in more detail with reference to FIGS. 4 & 5.

The transducer unit 1 of FIG. 2 is shown to be arranged for use in a vertical position. A stand 15 is provided to support the transducer unit 1 in such a way that the second open end (12 in FIG. 1) is not blocked. In the exemplary embodiment of FIG. 2, the stand 15 comprises a ring-shaped base from which support rods extend towards the hollow body 10, the base having a slightly larger diameter than the body 10. In this way, a stable vertical position is provided.

The embodiment of FIG. 1, in contrast, is more suitable to be used in a horizontal position, for instance in front of or underneath a television apparatus. Of course the embodiment of FIG. 1 may also be provided with suitable support elements if so desired.

In the alternative embodiment of FIG. 3, which may be used in a horizontal position or, with a suitable stand, in a vertical position, only second transducers 14 are provided, the first transducer(s) 13 having been omitted. This embodiment will later be explained in more detail with reference to FIG. 7.

In the embodiments shown in FIGS. 1-3, the transducer unit 1 has two open ends. However, the invention is not so limited and embodiments can be envisaged having only a single open end. The end 12 could be closed off, creating a closed chamber between the loudspeaker 13 and the end 12 of the hollow body 10. Alternatively, the loudspeaker 13 could be mounted so as to close off the end 12, possibly facing away from the interior of the hollow body 10. The internal diameter of the hollow body need not be constant but could be larger near the loudspeaker 13, thus creating a larger chamber.

The frequency mapping referred to above may be accomplished using a frequency mapping device 2 as illustrated in FIG. 4. The audio frequency mapping device 2 shown merely by way of non-limiting example in FIG. 4 comprises a band-pass filter 21, a detector 22, an (optional) low-pass filter 23, a multiplier 24 and a generator 25. The filter 21 has a pass-band which corresponds to a first audio frequency range I (as will later be explained in more detail with reference to FIG. 5), thus eliminating all frequencies outside the first range. The detector 22 detects the signal V_{F} received from the filter 21. The detector 22 preferably is a peak detector known per se, but may also be an envelope detector known per se. In a very economical embodiment, the detector may be constituted by a diode.

The signal V_{E} produced by the detector 22 represents the amplitude of the combined signals present within the first range I (see FIG. 5). Multiplier 24 multiplies the signal V_{E}, or its filtered version V_{E}′ if the optional filter 13 is present, by a signal V₀ having a frequency f_{w}. This signal V₀ may be generated by a suitable generator 25. The (amplitude modulated) output signal V_{M} of the multiplier 24 has an average frequency approximately equal to f_{w} while its amplitude is dependant on the signals contained in the first audio frequency range I. By varying the generator frequency f_{w}, the average frequency and therefore the location of the second audio frequency range II (FIG. 5) can be varied.

The audio frequency mapping device 2 is described in more detail in International Patent Application WO 2005/027568 referred to above, the entire contents of which are herewith incorporated in this document.

An exemplary distribution of audio frequency ranges is schematically illustrated in FIG. 5. A first frequency range I is shown, in this non-limiting example, to extend from 20 Hz to 100 Hz. This first frequency range I of the audio input signal (Vᵢₙ in FIG. 4) is mapped onto a second frequency range II, which is the present example is centered around 60 Hz. It can be seen that the second frequency range II (of the modulated signal V_{M} in FIG. 4) is narrower than and included in the first frequency range I.

In accordance with the present invention, the first transducer (13 in FIGS. 1 & 2) receives the second frequency range II, while the third frequency range III is received by the second transducers 14. In addition, the second frequency range II contains the frequency at which the transducer unit is most efficient, for example a resonance frequency but preferably the Helmholtz frequency of the transducer unit (1 in FIGS. 1-3). It is preferred that the second frequency range II is centered around this maximum efficiency frequency. If the second frequency range II is produced by the frequency mapping device 2 and the maximum efficiency frequency used is the Helmholtz frequency of the transducer unit, then the Helmholtz frequency f_{H} is preferably approximately equal to the generator frequency f_{w}. Expressed mathematically: f_{H}≈f_{w}.

A third frequency range III extends, in the example of FIG. 5, from 100 Hz upwards. This third frequency range is rendered by the second transducers 14 (see FIGS. 1-3). Accordingly, the first frequency range I is mapped upon a narrower frequency range II and reproduced by the first transducer 13 (FIGS. 1 & 2), while the third frequency range III is reproduced by the second transducers 14. It is noted that in the embodiment of FIG. 3, the second frequency range II is also reproduced by the second transducers 14.

In the example of FIG. 5 there is no overlap between the frequency ranges I and III, at least not at a certain amplitude level such as the −3 dB level. However, the present invention is not so limited and some overlap may occur, and may even be advantageous. However, any overlap between the second frequency range II and the third frequency range III is typically avoided.

The features of the present invention are embodied in the sound system 8 schematically shown in FIG. 6. In the non-limiting example shown, the sound system 8 comprises a transducer unit 1, a frequency mapping (FM) device 2, and a sound processing (SP) device 3. The sound system 8 may comprise further devices, such as a sound source (CD player, DVD player, MP3 player, Internet terminal, radio tuner), one or more amplifiers, and other units which are not shown for the sake of clarity.

The frequency mapping device 2 of FIG. 6 may correspond to the frequency mapping device 2 of FIG. 4 and preferably includes a band-pass filter (21 in FIG. 4) for band-pass filtering the input signal Vᵢₙ so as to select a frequency band (the first frequency range I in FIG. 5) to be mapped upon a resonance frequency f₀ or the Helmholtz frequency f_{H} of the transducer unit 1. The output signal V_{M} of the frequency mapping device 2 is fed to the first transducer (typically: loudspeaker) 13 to produce the Helmholtz frequency in dependence of the signal Vᵢₙ.

The sound processing device 3, which may be comprise an amplifier and/or one of more filters, receives an input signal V_{S} and outputs the signal Vᵢₙ and several signals x₁, x₂, . . . , xₙ. Each of the signals x₁, . . . , xₙ is fed to a transducer (typically: loudspeaker) 14 of the transducer unit 1. The signal Vᵢₙ is received by the frequency mapping (FM) unit 2 and transformed into the signal V_{M}, which is fed to the first transducer 13 of the transducer unit 1.

The sound processing device 3 may comprise a sound direction unit for producing directional sound signals. That is, the signals x₁ . . . xₙ are derived from the signal V_{S} in such a way (for example by introducing suitable relative delays) that the combined sound, when reproduced by the transducer unit 1, has a certain controlled direction relative to the transducer unit. Delay-and-sum beamforming is well known, reference is made to the paper by B. D. van Veen & K. M. Buckley, “Beamforming: A versatile approach to spatial filtering, IEEE ASSP Magazine, pp. 4-24, Vol. 5, No. 2, April 1988, the entire contents of which are herewith incorporated in this document.

It will be understood that the input signal V_{S} is not limited to a single channel (mono) signal and that this signal may be a stereo or multiple channel signal, such as a 5.1 signal. The sound system 8 may include more than one transducer unit 1, for example two, three, four or five such units. In the sound system of the present invention, it is not required to provide a separate sub-woofer unit as the (lower) bass sound may be reproduced at a satisfactory level by the transducer unit(s) 1.

The sound system 8 of FIG. 6 is designed for use with the transducer unit 1 according to FIGS. 1 & 2, in which a first transducer 13 is present. In accordance with the present invention, the first transducer 13 is operated at a maximum efficiency frequency of the transducer unit, such as a resonance frequency but preferably the Helmholtz frequency of the transducer unit. The alternative embodiment of the sound system 8′ which is illustrated in FIG. 7 is designed for use with the transducer unit 1′ of FIG. 3, in which no first transducer 13 is present.

The exemplary sound system 8′ of FIG. 7 comprises a transducer unit 1′, a frequency mapping (FM) device 2, a sound processing (SP) device 3, and combination units 5. The sound system 8′ may comprise additional devices, such as a sound source (CD player, DVD player, MP3 player, Internet terminal, radio tuner), one or more amplifiers, and other units which are not shown for the sake of clarity.

The combination units 5 each receive the signal V_{M} output by the frequency mapping (FM) unit 2 and a signal xᵢ (i=1 . . . n) output by the sound processing (SP) unit 3, the respective combined signals each being output to a (second) transducer 14. Accordingly, each of the transducers 14 reproduces an individual signal xᵢ and the signal V_{M}. Gain control units (not shown) may be provided to control the gain of the signal V_{M} relative to the signals xᵢ. If only a single (second) transducer 14 is used, the sound processing device 3 may be replaced by a simple connection, thus making the signals Vᵢₙ and x₁ identical to V_{S}.

The present invention is based upon the insight that a transducer unit designed to operate its resonance or Helmholtz frequency may advantageously include one or more additional transducers for reproducing additional sound frequencies. The present invention benefits from the further insight that plural additional transducers allow the sound to be steered in a certain direction.

The present invention is not limited to conventional electro-magnetic loudspeakers having a magnet, a coil and a cone, but may also be applied to other audio transducers, such as electrostatic loudspeakers.

It is noted that any terms used in this document should not be construed so as to limit the scope of the present invention. In particular, the words “comprise(s)” and “comprising” are not meant to exclude any elements not specifically stated. Single (circuit) elements may be substituted with multiple (circuit) elements or with their equivalents.

It will be understood by those skilled in the art that the present invention is not limited to the embodiments illustrated above and that many modifications and additions may be made without departing from the scope of the invention as defined in the appending claims.

1. A sound system (8), comprising a transducer unit (1) and a frequency mapping device (2), wherein the transducer unit comprises an array of transducers (14), and wherein the frequency mapping device is arranged for mapping a frequency range of an audio input signal (Vᵢₙ) onto a frequency at which the transducer unit has a maximum efficiency.

2. The sound system according to claim 1, wherein the frequency at which the transducer unit has a maximum efficiency is a resonance frequency of the transducer unit.

3. The sound system according to claim 1, wherein the frequency at which the transducer unit has a maximum efficiency is the Helmholtz frequency of the transducer unit.

4. The sound system according to claim 1, further comprising a sound processing device (3) arranged for steering sound produced by the array of transducers (14).

5. The sound system according to claim 1, wherein a dedicated transducer (13) is coupled to the frequency mapping device (2) so as to produce the Helmholtz frequency of the transducer unit (1).

6. The sound system according to claim 1, wherein the array of transducers (14) is coupled to the frequency mapping device (2) so as to produce the Helmholtz frequency of the transducer unit (1).

7. The sound system according to claim 6, further comprising combination units (5) for combining a frequency mapped signal (V_{M}) with array signals (x₁, . . . , xₙ).

8. The sound system according to claim 1, wherein the array of the transducer unit (1) comprises at least three transducers (14), preferably at least five transducers (14).

9. The sound system according to claim 4, wherein the frequency mapping device (2) and the sound processing device (3) are incorporated in the transducer unit (1).

10. The sound system according to claim 1, comprising at least two transducer units (1) and an amplifier device.

11. A method of reproducing sound using a transducer unit comprising an array of transducers (14), the method comprising the step of mapping a frequency range of an audio input signal (Vᵢₙ) onto a frequency at which the transducer unit has a maximum efficiency.

12. The method according to claim 11, wherein the frequency at which the transducer unit has a maximum efficiency is a resonance frequency of the transducer unit.

13. The method according to claim 11, wherein the frequency at which the transducer unit has a maximum efficiency is the Helmholtz frequency of the transducer unit.

14. The method according to claim 11, further comprising the step of steering sound produced by the array of transducers (14).

15. A computer program product for carrying out the method according to claim 11.
